(19) United States
(12) Patent Application Publication
(10) Pub. No.: US 2005/0071730 A1
(43) Pub. Date: Mar. 31, 2005

(54) Continuous self-verify of configuration memory in programmable logic devices

(75) Inventors: Mark Moyer, Austin, TX (US); Jeffrey Byrne, Portland, OR (US)

Correspondence Address: Jon W. Hallman;MacPHERSON KWOK CHEN & HEID LLP, 1762 Technology Drive, Suite 226, San Jose, CA, 95110, US

(73) Assignee: Lattice Semiconductor Corporation

(21) Appl. No.: 10/676,494

(22) Filed: Sep. 30, 2003

(51) Int. Cl. H03M 13/00; G11C 29/00

(52) U.S. Cl. 714/758

(57) ABSTRACT

A programmable logic device (PLD) such as an FPGA or CPLD is supplementally configured to verify the integrity of its configuration data during operation of the device. The programmable logic device includes a checksum calculation engine to calculate a checksum based upon the configuration data. A checksum comparator compares the calculated checksum to a previously-calculated checksum to verify the integrity of the configuration data.

### TECHNICAL FIELD

The present invention relates generally to programmable logic device reliability, and more particularly to a programmable logic device configured to verify its configuration memory during operation of the device.

### BACKGROUND

A user may configure a programmable logic device (PLD) such as a field programmable gate array (FPGA) or complex programmable logic device (CPLD) to perform a desired function and thus avoid having to design an application specific integrated circuit (ASIC) to perform the same task. Because designs and system requirements may change and evolve, users of programmable logic devices can simply reprogram these devices without having to engineer another ASIC. Although programmable logic devices thus offer users significant advantages, a concern may be raised concerning their configurability. Specifically, the configuration of programmable logic devices often depends upon a volatile configuration memory such as RAM that may become corrupted during programmable logic device operation. Should a configuration bit in the configuration memory change its value, a programmable logic device may cease to perform the function desired by a user. In critical applications, such a failure could be disastrous.

Volatile configuration memory may become corrupted in a number of ways. For example, all materials, including the semiconductor substrate used to form a configuration memory, are naturally radioactive. Although this natural level of radioactivity is quite low, it still involves the emission of alpha particles. These high energy particles may then interact with a memory cell and corrupt its value. Alternatively, power brownout, i.e., a glitch or drop in supply voltages over a certain duration, may corrupt the programmed value of the memory cells.

In the current state of the art, a programmable logic device user may verify configuration memory contents during the configuration process. However, a user then has no way to re-verify the configuration memory contents during subsequent operation of the programmable logic device (i.e.; while the device is operable to accept input data and generate output data), despite the multiple ways in which the configuration memory may become compromised such as those discussed above.

Accordingly, there is a need in the art for programmable logic devices configured to allow the verification of the configuration memory during programmable logic device operation.

### SUMMARY

One aspect of the invention relates to a programmable logic device including a configuration memory operable to store configuration data. A checksum calculation engine is operable to cyclically process the configuration data during operation of the programmable logic device using an error detection algorithm. The checksum calculation engine calculates a checksum during each calculation cycle. A checksum comparator is operable to compare the checksum calculated by the checksum calculation engine in a given calculation cycle with a previously-calculated checksum to verify the integrity of the configuration data.

In accordance with another aspect of the invention, a method is provided that includes the acts of configuring a programmable logic device with configuration data; operating the configured programmable logic device; during operation of the programmable logic device, cyclically processing the configuration data using an error-detection algorithm to generate a checksum during each calculation cycle; and after each calculation cycle, comparing the generated checksum with a previously-calculated checksum to verify the integrity of the configuration data.

### BRIEF DESCRIPTION OF THE DRAWINGS

FIG. 1 is a block diagram overview of configuration memory self-verification system according to one embodiment of the invention.

FIG. 2 is a block diagram of a CRC calculation engine for the configuration memory self-verification system of FIG. 1 according to one embodiment of the invention.

FIG. 3 is an exemplary flowchart and control block diagram for an IP-based self-verification technique according to one embodiment of the invention.

Use of the same reference symbols in different figures indicates similar or identical items.

### DETAILED DESCRIPTION

The present invention provides a programmable logic device that may verify the contents of its configuration memory during normal operation. To enable this verification, a conventional programmable logic device may be modified with hardware dedicated to the verification task. Alternatively, a conventional programmable logic device may be programmed to perform this verification without the use of dedicated hardware in what may be denoted as an “IP-based” approach. As will be explained in further detail herein, each approach has its own benefits as will be discussed further herein. The dedicated hardware embodiment will be described first.

Dedicated Hardware for Self-Verification

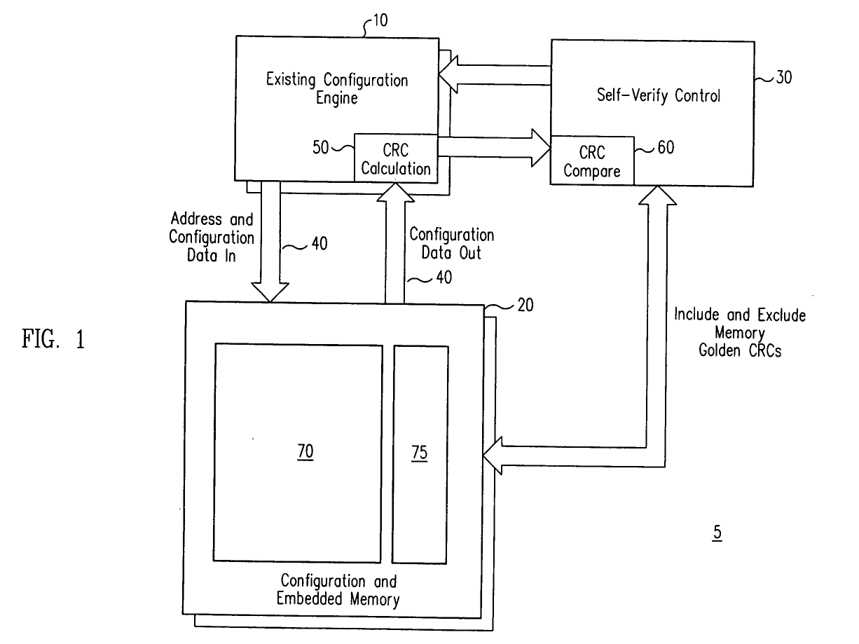

FIG. 1 is a high-level block diagram of a programmable logic device 5 constructed according to one embodiment of the invention. The PLD 5 includes a configuration engine 10 for writing configuration data to a configuration memory 20. The PLD 5 also includes a self-verify control module 30 coupled to the engine 10 and memory 20. Configuration engine 10 may be of conventional design.

As is known in the art, to program the configuration memory 20, a user couples an external programming tool to configuration engine 10. During the subsequent configuration, configuration engine 10 sequentially addresses all memory locations within configuration memory 20 so that the appropriate configuration data may be written into these locations. The addresses and configuration data couple from configuration engine 20 to configuration memory 10 over a system bus 40.

Once all the configuration data has been written into the configuration memory, the programmable logic device 5 may commence operation, implementing the logical functions desired by a user. Should the configuration data become corrupted, the subsequent operation of the programmable logic device may fail to satisfy a user's requirements. Thus, during operation of the programmable logic device, self-verify control module 30 controls the continuous verification of the configuration data stored in configuration memory 10 to detect any corruption. The stored configuration data are verified by processing with an error detection algorithm. Should an error be detected, self-verify control module 30 signals the faulty condition.

Configuration data serves different purposes within a programmable logic device. For example, rather than being used to configure the behavior of logical blocks, certain configuration memory cells may be used as memory storage in embedded read-only memory blocks within the programmable logic device. Moreover, other configuration memory cells may be used to form random access memory blocks within the programmable logic device. Thus, memory cells within configuration memory 20 may be classified into two categories: a first category 70 of memory cells that are programmed during configuration and whose contents do not thereafter change during operation of the programmable logic device in a-read-only fashion; and a second category 75 of memory cells that are programmed during configuration and whose contents may thereafter change during operation of the programmable logic device (i.e., used as RAM). In the first category 70 would be configuration memory cells used to control the configuration of logic blocks or used to form an embedded read-only memory. In the second category 75 would be configuration memory cells used to form embedded random access memories. Because configuration memory cells in the second category may change their contents during operation of the device, they should be excluded from verification by self-verify control module 30. If these dynamically-reconfigurable configuration memory cells were not excluded, self-verify control module 30 would detect their content change and erroneously assume that the configuration memory has become corrupted. The exclusion of such memory cells from a self-verification may be implemented in a number of ways as discussed further herein.

To verify its integrity, configuration data written into configuration memory 20 is retrieved during operation of the programmable logic device. Because configuration engine 10 uses system bus 40 to load the configuration data into configuration memory 20 during configuration, it is efficient to also use system bus 40 to retrieve the configuration data during self-verification. It will be appreciated, however, that, alternatively, a separate bus may be used to retrieve the configuration data so that the error detection analysis may be performed.

Any suitable error detection algorithm may be used within PLD 5 to perform the self-verification of the configuration data, such as an algorithm that derives values from the configuration data. Preferably, the PLD uses the same algorithm used by the external programming tool to verify the configuration data during the configuration process. For example, the PLD and the programming tool may each use a same algorithm that calculates a checksum for the configuration data. As is known in the error detection arts, a checksum is a number that depends upon the data being examined. Should the contents of the data being error detected change, the checksum should also change. However, depending upon how robust the particular error detection algorithm being implemented is, the checksum may not change even though the data has become corrupted. For example, a simple parity bit checksum will not detect an error should just two bits in the original data change polarity. This type of undetected error condition may be denoted as aliasing. More sophisticated error detection algorithms will generate a checksum that will change its value with high probability if the data has become corrupted. For example, a variety of cyclic redundancy check (CRC) algorithms will generate checksums (often denoted as a frame check sequence (FCS)) that are robust to aliasing. Accordingly, the following discussion will assume that a CRC error detection technique is implemented. However, it will be appreciated that other types of error detection algorithms and techniques may be used, e.g., parity checks A or linear feedback shift register techniques.

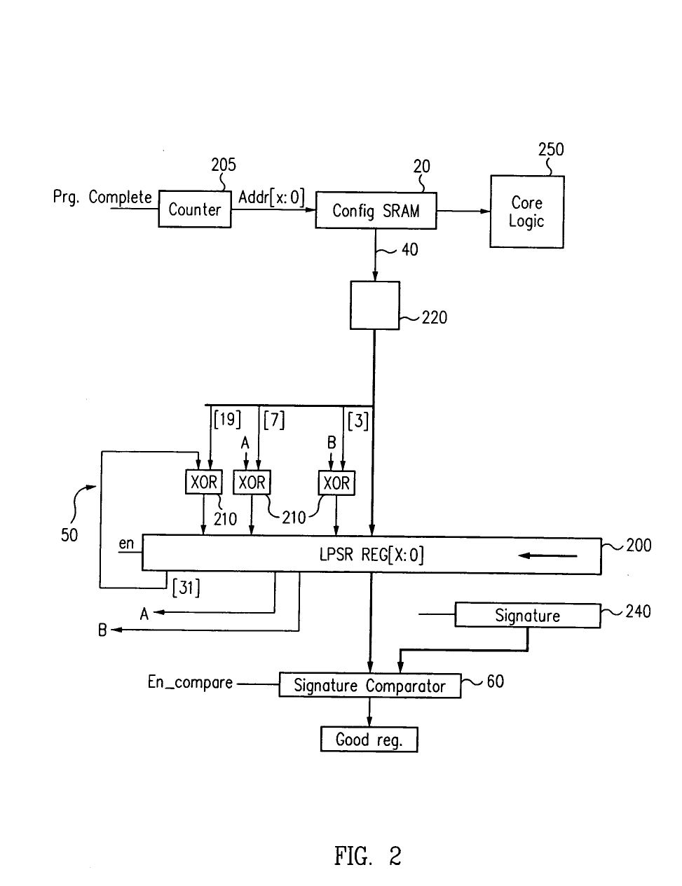

Assuming system bus 40 is used for configuration data retrieval, a natural location for a CRC calculation module 50 is within configuration engine 10. However, CRC calculation module 50 may be located wherever it is suitable within the programmable logic device. During configuration, the external programming tool will calculate the CRC checksum associated with the set of configuration data being loaded into the programmable logic device. As used herein, this initial CRC checksum will be referred to as the “golden” CRC. Configuration engine 10 loads the golden CRC into a storage register 240 (FIG. 2) in PLD 5 which may be separate from configuration memory 20. Alternatively, configuration engine 10 may load the golden CRC into configuration memory 20 along with the rest of the configuration data although such a loading complicates the self-verification process. During self-verification, self-verify control module 30 compares the current CRC checksum calculated by CRC calculation module 50 against the golden CRC value using a CRC comparator module 60. Should these values be the same, no errors are detected. However, if these values differ, self-verify control module 30 will indicate that an error has been detected.

As discussed above, embedded memory blocks that depend upon configuration memory cells for memory storage may be either read-only memory blocks that are configured during configuration and do not change their contents during operation or random access memory blocks that are reconfigurable during operation. In either case, additional configuration memory cells will be used in their normal “configuration” fashion, i.e., used to configure the data width and depth of the embedded memory blocks and other associated configurable features. Such configuration memory cells should be verified to ensure proper operation of the configured programmable logic device. However, the configuration memory cells used for storage in embedded memory blocks configured as random access memories should not be included in the self verification because their contents may change during normal operation without any error conditions being present. In conventional programmable logic devices, configuration memory cells used for storage in embedded memory blocks configured as read-only memories may not be accessible to configuration engine 10 during normal operation of the programmable logic device. Accordingly, such embedded memory blocks will have to be modified such that their memory cells may be accessed by configuration engine 10 during self-verification. In the absence of dedicated hardware such as in the IP-based approach discussed below, these “inaccessible” configuration memory cells would have to be verified separately as will be explained further herein.

To indicate whether an embedded memory block's memory cells should be included in the CRC checksum calculation, each embedded memory block may be associated with an indicator such as a status bit that indicates whether it is read-only or random access. Should the status bit indicate that a particular embedded memory block is configured as random access memory, self-verify control module 30 will exclude the configuration data stored in its memory cells from the CRC checksum calculation.

A programmable logic device's logic blocks may also be configured as memory. For example, the configuration memory cells storing a LUT-based logic block's truth table may instead be used as a random access memory. Thus, each logic block may also be associated with a status bit indicating whether any of its configuration memory cells are being used as random access memory so that they may be excluded from the CRC checksum calculation in the same fashion.

Rather than use a bit to indicate whether a configuration memory cell's contents should be excluded from an error detection process, the external programming tool could use as the indicator the addresses of configuration memory locations storing configuration data that may be changed during programmable logic device operation. These addresses would be stored in configuration memory 20 along with the remaining configuration data. Upon retrieval of the configuration data by module 10 during self-verification, configuration data from the addresses noted by the external programming tool would be excluded.

CRC calculation module 50 may be implemented in a number of fashions. For example, a linear feedback shift register (LFSR) 200 may be used to form CRC calculation module 50 as seen in FIG. 2. Depending upon the particular CRC generating polynomial desired, certain bits in the LFSR are XOR'ed in XOR gates 210 with bits in each retrieved configuration data word.

To begin a self-verification cycle, self-verify control module 30 (FIG. 1) signals a counter 205 included in module 50 to begin counting through all available addresses for configuration memory 20. Responsive to each address from counter 205, the corresponding configuration data word is retrieved from configuration memory 20 on bus 40. As described above, configuration memory cells that may be reconfigured during operation of the programmable logic device should be excluded from the CRC calculation. Denoting which configuration memory cells should be excluded may occur in a number of ways. Should the denotation be made through use of a status bit, a test module 220 may test each status bit to indicate whether LFSR 200 should process the associated configuration data word. If the status bit indicates the associated configuration data word should not be processed, test module 220 blocks the word from coupling to LFSR 200. In this case, LFSR 200 simply maintains its current value. Should the status bit indicate that the associated configuration data word should be processed, test module 220 allows it to couple to LFSR 200. Note, however, that “blocked” configuration data may couple assuming that predetermined values are used. For example, the blocked configuration data may be considered to be all logical high values or logical low values. By successively processing each retrieved data word that couples through test module 220 as counter 205 cycles through every address in configuration memory 20, LFSR 200 eventually stores the CRC checksum for the configuration data. Counter 205 then indicates to self-verify control module 30 that all addresses have been counted so that LFSR 200 may be commanded to provide the CRC checksum to CRC comparator 60. CRC comparator 60 then compares the CRC checksum to the golden CRC checksum retrieved from storage register 240. If the golden CRC checksum and the CRC checksum are the same, a device_good flag is set to true and stored in a flag register 251 within self-verify control module 30. Otherwise, the device_good flag is set to false and then stored in flag register 250. The status of device_good flag may then be reported by module 30 to external devices so that a reconfiguration of the programmable device may be initiated. For example, should the external devices include a microprocessor, an interrupt could be generated. Should programmable logic device 5 also include a non-volatile memory storing the configuration data, it could react to a bad device_good flag by automatically reloading the volatile configuration memory 20 from the non-volatile memory.

IP-Based Approach

In a software or IP-based approach, the self-verify control module 30, the CRC calculation engine 50, and the CRC comparator 60 would all be implemented by programming logic blocks within the programmable logic device to perform the required functions. As is known in the art, a user programs configuration memory 20 so that logic blocks within core logic 250 (FIG. 2) perform the desired functions. In an IP-based approach, configuration memory 20 would be configured so as to command core logic 250 to perform the self-verification technique disclosed herein. Because no hardware modifications are made in an IP-based approach, there would be no need for a storage register 240 to store a golden CRC calculated by an external programming tool. Thus, in an IP-based approach, the core logic 250 would, in its first self-verification cycle, calculate a CRC checksum and designate this as the golden CRC. The lack of hardware modifications provides another functional difference from the previously-described dedicated hardware approach. In general, a programmable logic device will have a configuration engine 10 that may be commanded to retrieve configuration data over system bus 40. However, certain configuration memory cells used for storage in embedded read-only memory blocks may be inaccessible for retrieval in this fashion. Thus, in an IP-based approach, a separate self-verification process may be used for such inaccessible configuration memory cells.

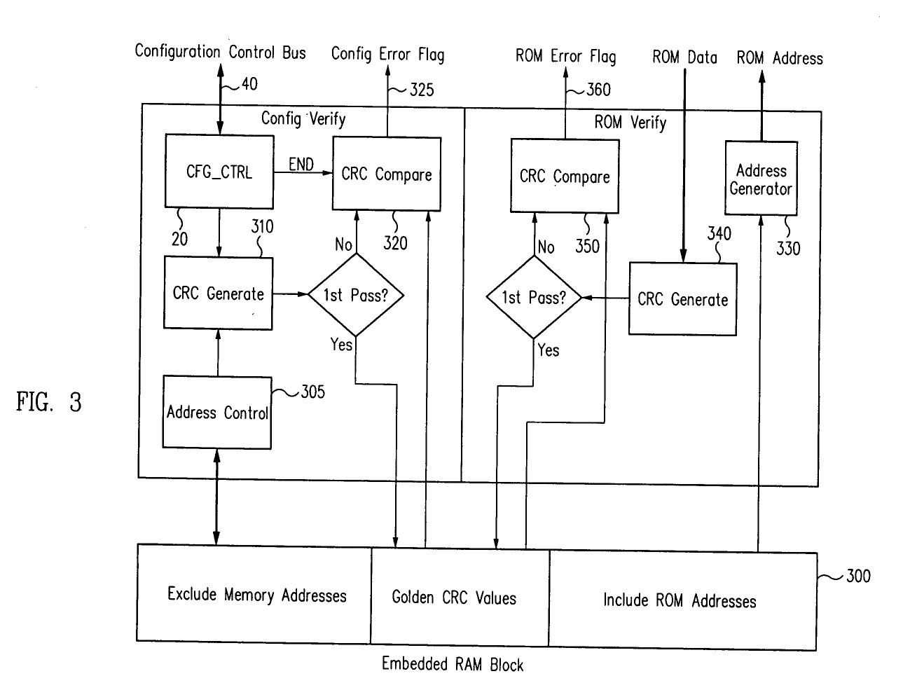

An exemplary flowchart and control block for an IP-based self-verification technique is illustrated in FIG. 3. Configuration engine 20 is commanded to retrieve configuration data words over system bus 40 as described previously. In this exemplary flowchart, it is assumed that configuration memory cells used as storage in embedded ROM blocks are inaccessible to configuration engine 20 and are thus verified separately. Retrieved configuration data words from configuration engine 20 are processed in a CRC engine 310. An embedded RAM block 300 stores the addresses of configuration memory locations storing configuration data words that should be excluded from configuration engine 20 (for configuration data within category 75 of FIG. 1). An external programming tool would write addresses to be excluded into embedded RAM block 300 during configuration. An address control module 305 extracts the addresses from embedded RAM block and prevents CRC engine 310 from processing configuration data words at the excluded addresses. After processing all possible configuration data words, CRC engine 310 calculates the CRC checksum. If this is the first self-verification cycle by CRC engine 50, it is deemed the golden CRC and stored in embedded RAM block 300. Otherwise, the golden CRC and the currently-calculated CRC checksum are compared in a comparator 320 to determine the state of a configuration error flag 325.

The verification of configuration data in configuration memory locations used for memory in embedded ROM blocks proceeds analogously. Only those embedded ROM blocks that are configured need be verified. Thus, during configuration, the addresses of configuration data memory locations that will be used as storage for embedded ROM blocks are written into embedded RAM block 300. During self-verification, an address generator 330 reads the used configuration data memory locations from RAM block 300 so that the corresponding configuration data may be retrieved and processed by a CRC engine 340. If this is the first self-verification cycle by CRC engine 340, the resulting CRC checksum is designated the golden CRC and stored in RAM block 300. Otherwise, the golden CRC and the currently-calculated CRC checksum are compared in a comparator 350 to determine the state of a ROM error flag 360. CRC engines 310 and 340, CRC comparators 320 and 350, address control module 305, and address generator 330 would all be implemented in programming core logic 250 (FIG. 2) of programmable logic device 5 (FIG. 1). In contrast to a dedicated hardware approach, the performance of these modules depends upon the integrity of the configuration data they are tasked to verify. As such, it is possible that configuration data could be corrupted such that these modules “crashed” such that the error flags would remain in a “device good” mode. A “watchdog” may be implemented in core logic 250 to detect such a malfunction. For example, the flags could be periodically toggled or compared using a timer.

ROM error flag 360 and configuration error flag 310 may be received by external devices so that programmable logic device 5 may be reconfigured. Alternatively, these flags may be OR'd together before reporting the results to an external device. In addition, these flags may be used internally by programmable logic device 5. For example, should programmable logic device 5 contain a non-volatile configuration memory, it may respond to a faulty condition expressed by either of these flags by reconfiguring volatile configuration memory 20 from the non-volatile configuration memory.

The above-described embodiments of the present invention are merely meant to be illustrative and not limiting. It will thus be obvious to those skilled in the art that various changes and modifications may be made without departing from this invention in its broader aspects. For example, other error detection algorithms including but not limited to parity bit schemes may be used in lieu of a CRC checksum calculation. Accordingly, the appended claims encompass all such changes and modifications as fall within the true spirit and scope of this invention.

1. A programmable logic device, comprising:
a configuration memory operable to store configuration data;
a checksum calculation engine operable to cyclically process the configuration data during operation of the programmable logic device using an error detection algorithm, the checksum calculation engine calculating a checksum during each calculation cycle, and
a checksum comparator configured to compare the checksum calculated by the checksum calculation engine in a given calculation cycle with a previously-calculated checksum so as to verify the integrity of the configuration data.

2. The programmable logic device of claim 1, wherein the checksum calculation engine is a CRC calculation engine, and wherein the checksum comparator is a CRC checksum comparator.

3. The programmable logic device of claim 1, wherein the checksum calculation engine is a parity bit calculation engine, and the checksum comparator is a parity bit checksum comparator.

4. The programmable logic device of claim 1, wherein the configuration memory is a volatile configuration memory operable to store a first type of configuration data that may be reconfigured during operation of the programmable logic device and a second type of configuration data that will not be reconfigured during operation of the programmable logic device, the programmable logic device further comprising a self-verification control module for controlling the checksum calculation engine to exclude from processing the first type of configuration data.

5. The programmable logic device of claim 2, wherein the CRC calculation engine comprises a linear feedback shift register (LFSR).

6. The programmable logic device of claim 2, further comprising:
a register operable to store a predetermined CRC checksum, wherein the previously-calculated checksum used by the CRC checksum comparator is the predetermined CRC checksum.

7. The programmable logic device of claim 1, wherein the checksum calculation engine is configured to calculate an initial checksum during its initial cycle, and wherein the previously-calculated checksum used by the checksum comparator is the initial checksum.

8. The programmable logic device of claim 4, wherein the configuration data of the first type are associated with test bits, and wherein the self-verify control module is responsive to the test bits to control the checksum calculation engine to exclude from processing the first type of configuration data.

9. The programmable logic device of claim 1, further comprising:
a configurable logic core, wherein the checksum calculation engine and the checksum comparator are each implemented by configuring the logic core.

10. The programmable logic device of claim 1, wherein the checksum calculation engine and the checksum comparator each comprises dedicated hardware.

11. A programmable logic device, comprising:
a configuration memory operable to store configuration data; and
error-checking means for cyclically processing the configuration data during operation of the programmable logic device with an error detection algorithm so as to calculate a checksum during each calculation cycle and for comparing the checksum calculated in a given calculation cycle with a previously-calculated checksum.

12. The programmable logic device of claim 11, wherein the error-checking means is configured to cyclically process the configuration data during operation of the programmable logic device with a CRC algorithm so as to calculate a CRC checksum during each cycle and to compare the CRC checksum calculated in a given cycle with a previously-calculated CRC checksum.

13. The programmable logic device of claim 12, wherein error-checking means is configured to compare the CRC checksum calculated in a given cycle with a predetermined CRC checksum.

14. The programmable logic device of claim 12, wherein the configuration memory is a volatile configuration memory operable to store a first type of configuration data that may be reconfigured during operation of the programmable logic device and a second type of configuration data that will not be reconfigured during operation of the programmable logic device, and wherein the error-checking means is configured to cyclically process only the second type of configuration data.

15. A method, comprising:
(a) configuring a programmable logic device with configuration data;
operating the configured programmable logic device;
(b) during operation of the programmable logic device, cyclically processing the configuration data using an error-detection algorithm to generate a checksum during each calculation cycle; and
(c) after each calculation cycle, comparing the generated checksum with a previously-calculated checksum to verify the integrity of the configuration data.

16. The method of claim 1, wherein act (b) comprises cyclically processing the configuration data using a CRC algorithm to generate a CRC checksum during each cycle, and wherein act (c) comprises comparing the generated CRC checksum with a previously-calculated CRC checksum.

17. The method of claim 15, wherein act (a) comprises configuring the programmable logic device with configuration data such that the programmable logic device is configured to perform acts (b) and (c).

18. The method of claim 15, wherein the configuration data comprises a first type of configuration data that may be reconfigured during operation of the programmable logic device and a second type of configuration data that will not be reconfigured during operation of the programmable logic device, and wherein act (b) comprises cyclically processing only the second type of configuration data.

19. The method of claim 15, further comprising:
asserting a good configuration memory flag if the comparison in act (c) indicates that the integrity of the configuration memory has not been corrupted.

20. The method of claim 19, further comprising:
if the good configuration memory flag is not asserted, reconfiguring the programmable logic device with the configuration data.

21. A method of verifying the integrity of configuration data within a programmable logic device (PLD) during operation of the device, the method comprising:
providing in the device a first value derived from the configuration data at the time the configuration data is written into the PLD
calculating within the PLD a second value derived from the configuration data; and
comparing within the PLD the first value to the second value.

22. The method of claim 21, wherein the first and second values are derived according to a same error detection algorithm.

23. The method of claim 21, wherein the first and second values are checksums.

24. A programmable logic device, comprising:
a first value stored within the PLD and derived from the configuration data at the time the configuration data is written into the PLD;
a calculating circuit within the PLD and operable to calculate during operation of the PLD a second value derived from the configuration data; and
a comparator within the PLD and operable to compare during operation of the PLD the first value to the second value.
